(19) United States
(12) Patent Application Publication
(10) Pub. No.: US 2006/0257790 A1
(43) Pub. Date: Nov. 16, 2006

(54) A SEMICONDUCTOR DEVICE STRUCTURE AND METHODS OF MANUFACTURING THEREOF

(75) Inventors: LI-CHUN TIEN, Tainan (TW); MI-CHANG CHANG, Hsin-Chu (TW); HUANG-SHENG LIN, Hsin-Chu (TW); YU-CHYI HARN, Hsin-Chu County (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsinchu (TW)

(21) Appl. No.: 10/908,540

(22) Filed: May 16, 2005

(51) Int. Cl. G03F 9/00

(52) U.S. Cl. 430/311; 430/5

(57) ABSTRACT

Described is a semiconductor device structure with improved iso-dense bias and methods of producing thereof. Non-functional patterns may be added to an integrated circuit layout design. These patterns may be located next to an isolated transistor or an array of densely-packed transistors in order to mitigate the iso-dense bias effects. Furthermore, the patterns can take on a variety of geometric shapes and sizes.

### BACKGROUND

For an integrated circuit (IC) layout designer, there is often a desire to aggregate or densely-pack multiple gate transistors within a certain area of an IC layout while other regions are laid out to have isolated or stand-alone gates. This variation in transistor density within an IC design can influence a transistor's feature size or critical dimension during semiconductor processing. In particular, irregularities of features sizes can become evident during photolithography and those irregularities may be amplified during subsequent deposition or etch processes. In other words, a group of densely-packed transistors may print or etch differently than an isolated transistor, even if they both have common designs within a layout.

The feature size irregularity is due to diffraction and interference effects of light waves as illustrated in FIGS. 1A-1B, which shows a light 102 passing through an isolated feature 104 and a group of densely-packed features 114 in a photolithography mask 106 in side view. The effects become even more significant as transistor dimensions shrink within sub-micron regime. When light 102 radiates toward an isolated feature 104 in a photomask 106 as shown in FIG. 1A, the light diffracts uniformly as it passes through the feature aperture 104. Beneath the isolated feature 104, the underlying wafer 108 will experience maximum intensity beneath the center of the feature 104, with the intensity tapering off toward the edges in a Gaussian bell-shaped intensity distribution profile 110 as illustrated.

FIG. 1B illustrates a diffraction pattern for an array of densely-packed features 114. The resulting intensity distribution in this instance will be dominated by interference effects due to neighboring features leading to constructive and destructive interference fringe patterns. Like with a single aperture 104, light waves 102 traveling through multiple apertures 114 in a photomask 106 also diffract uniformly as they pass through the apertures 114. However, circular waves emitted by one aperture can interfere with circular waves coming out of another aperture. If the light waves are “in phase” when they collide, meaning that they match up exactly or that they experience “constructive interference,” then the waves will combine for maximum intensity. If the light waves are “out of phase” when they collide, meaning that they are off by one-half cycle or that they experience “destructive interference,” then a crest from one wave merges with a trough from another wave, resulting in waves with minimum intensity.

Densely-packed features 114, due to the interference phenomenon from neighbors, will thereby produce an intensity profile with sinusoidal interference fringe pattern 120. Furthermore, the intensity will be at their greatest near the center of the array and taper off toward the edges, with the result that features near the center will print with better fidelity and confidence because they will see more light, while those near the edges will see less light, as illustrated by the intensity profile 120. As an example, assume densely-packed features 114 comprising patterns for five lines. Due to interference fringe pattern from neighboring features and the resulting intensity profile 120, the three lines in the center may be reproduced on the wafer 108 with a more accurate critical dimension than the two outer lines.

As a result of the difference in intensity, isolated 104 and densely-packed 114 features within an IC design will print with different fidelity, resulting in features with different critical dimensions or linewidths. Such a phenomenon is sometimes referred to as the iso-dense bias effect in photolithography. In addition, there may also be uniformity concerns between isolated 104 and densely-packed 114 features across a wafer 108 as the drive towards smaller feature size and larger substrate continues.

Techniques at minimizing the iso-dense bias have included improving the photolithographic processes or utilizing advanced photoresist chemical systems. Other methods include optical corrections with phase-shifting photomasks or off-axis illumination. For further discussion, please refer to a publication by Uzodinma Okoroanyanwu, Materials and Process Issues Delaying the Introduction of ArF into Production, 12 FUTURE FAB INTL. Ch. 5 (2002), available at http://www.future-fab.com/documents.asp?d_ID=925#. However, most of these techniques and methods consume valuable resources and sometimes require accurate and delicate processing controls. Therefore, there exists a need for controlling the iso-dense bias effect with maximum efficiency and minimum cost.

### SUMMARY

Described is a semiconductor device structure with improved fidelity and uniformity and methods of manufacturing thereof. An integrated circuit layout with multiple functional devices such as logic cells and multiplexers having functional patterns are initially defined. Within the layout, at least one layer of non-functional patterns may be physically positioned adjacent to the functional patterns of the at least one layer of functional patterns. The non-functional patterns can take on a plurality of shapes and sizes. Furthermore, at least one layer of filler cells may also be incorporated within the layout adjacent to the functional patterns, whereby the layer of filler cells includes at least one non-functional pattern.

### BRIEF DESCRIPTION OF THE DRAWINGS

FIGS. 1A-1B illustrate the diffraction and interference effects of isolated and densely-packed features;

FIG. 2 illustrates a conventional functional device;

FIG. 3 illustrates a functional device using the disclosed embodiment;

FIG. 4 illustrates a filler cell using the disclosed embodiment;

FIG. 5 illustrates functional devices using the disclosed non-functional pattern embodiments; and

FIGS. 6A-6B compare the difference between a conventional integrated circuit layout and one utilizing the presently disclosed embodiments.

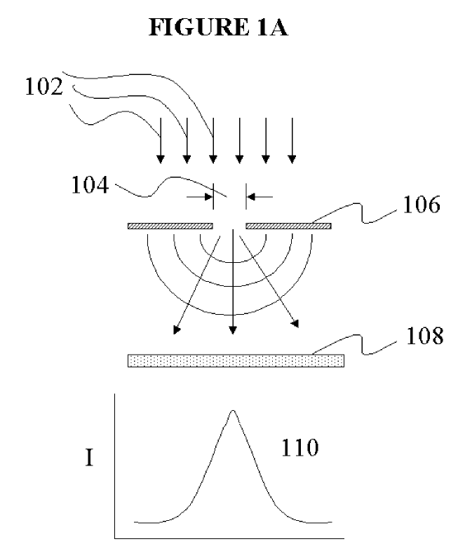

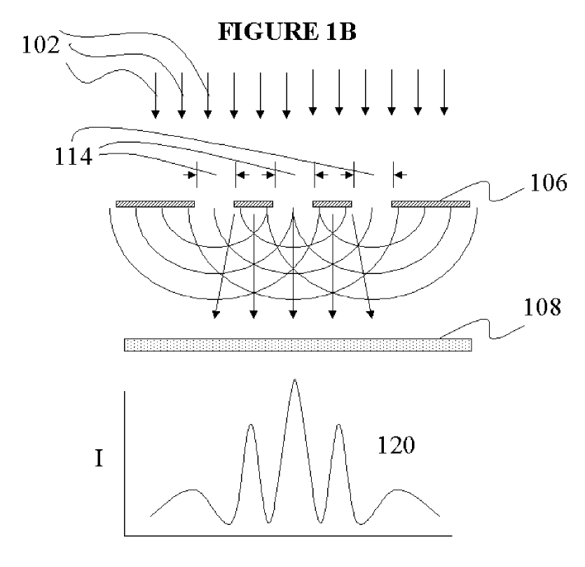

### DETAILED DESCRIPTION

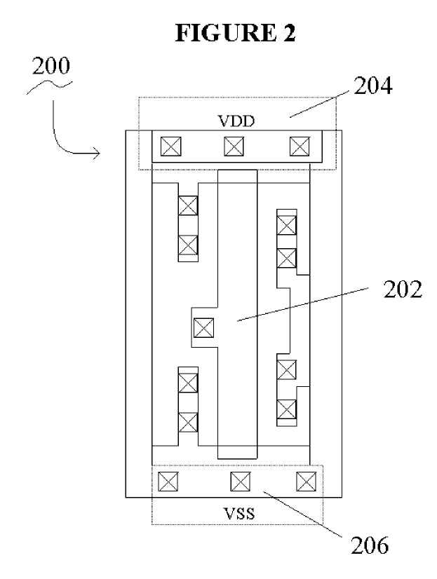

Reference is now made to a conventional functional device 200 as illustrated in FIG. 2. As shown in the figure, the functional device 200 contains a functional pattern 202 surrounded by a VDD region 204 and a VSS region 206. The functional device 200 may be an electronic logic gate such as an INV (inverter), NAND (not and), NOR (not or), AND (logic operation where the output is high only if all inputs are high), XOR (exclusive or), or a F/F (flip-flop) circuit. In addition, the functional device 200 may also be a multiplexer or a design that combines two or more signals onto a single line. There may be a plurality of functional devices 200 within an IC layout design.

A functional device 200 on a semiconductor wafer may contain various components. These components are constructed of multiple layers of materials in complex patterns depending on device requirements. The layers are produced when complex photomask patterns are reduced onto a semiconductor substrate by photolithographic processes. For example, with a complementary metal oxide semiconductor (CMOS) device, source and drain regions may initially be formed on the substrate, followed by polysilicon gates, aluminum metal lines, passivation layers, and so forth. Additional layers may be repeated or reproduced with different designs to form the desired functional device 200.

Photolithography of a conventional functional device 200 without the presently disclosed embodiments will result in an underlying wafer experiencing maximum intensity beneath the center of the functional pattern 202, with the intensity tapering off toward the edges in a Gaussian bell-shaped intensity distribution profile as previously discussed. Likewise, a conventional functional device 200 with densely-packed functional patterns (not shown) without the presently disclosed embodiments will experience interference phenomenon from neighboring functional patterns. The result is an intensity profile with sinusoidal interference fringe pattern beneath the densely-packed functional patterns (not shown) as previously discussed. Due to this fringe pattern, certain layers of the functional cell 200 may not be as sharp and precisely formed as is desirable.

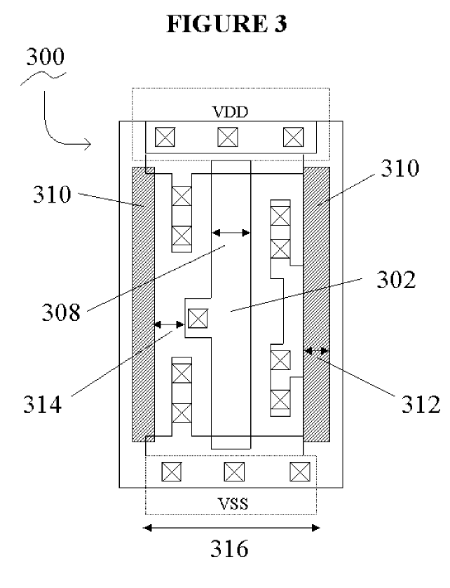

FIG. 3 illustrates how non-functional patterns 310 may be included on a layer with functional patterns 302 of a functional device 300 to mitigate the effects of the iso-dense bias. A functional device 300 with an isolated functional pattern 302 on a given layer is illustrated in the figure. By adding non-functional patterns 310 to a layer or layers of the functional patterns 302 forming the functional device 300, the intensity profile on an underlying wafer may be manipulated to reflect that of an array of densely-packed features. In other words, rather than an isolated functional pattern 302, the image will instead include a densely-packed array of features with one functional pattern 302 and two non-functional patterns 310 generally about its perimeter. Additionally, the densely-packed array of features may also be one functional pattern 302 and four non-functional patterns 310 generally about its perimeter (not shown). The ability to add or remove non-functional patterns 310 to or from the layers of a functional device 300 thereby allows an IC layout designer to control feature size intensity profiles, which can in turn dictate feature fidelity and uniformity. A non-functional pattern 310 thereby balances and controls adjacent image intensity profiles on a localized level.

Additionally, the non-functional patterns 310 may also reduce loading effects during chemical removal processes, such as wet etch, dry etch, or chemical mechanical processing (CMP) near functional patterns 302 on a global wafer level. By balancing adjacent image intensity profiles on a localized level, a functional device 300 will have an overall balance with good image fidelity and uniformity. As more and more functional devices 300 are printed on a substrate, the wafer will have optimized loading effects because any imbalance has been minimized by the addition of non-functional patterns 310 adjacent to functional patterns 302, thereby allowing both patterns 310, 302 to experience favorable chemical removal processes. The non-functional patterns 310 balance feature densities on a microscopic or localized level, as well as an overall greater balance on a macroscopic or global wafer level, thereby producing functional devices 300 with generally better critical dimension control and wafers with optimal surface planarization.

In one embodiment, the non-functional patterns 310 may be a metal, a semiconductor, or a combination thereof. In another embodiment, the layer of non-functional pattern 310 may be a metal layer, a polysilicon layer, a semiconductor layer, or a combination layer thereof. In yet another embodiment, the non-functional pattern 310 may be formed of a semiconductor substrate. The resulting material formed on the functional device by the non-functional patterns 310 will be driven by material used for the functional patterns 302 of the layer of interest. In addition, although the non-functional pattern 310 as illustrated is rectangular in shape, it can take on any polygonal shape such as a triangle, a square, a parallelogram, a diamond, or a trapezoid. Furthermore, the non-functional pattern 310 may also be in the shape of a plane curve such as a circle, an ellipse, a line, a parabola, or a hyperbola.

There are certain requirements that these non-functional features 310 may be designed to satisfy. In one embodiment, the total area of the non-functional patterns 310 may be designed to be substantially the same as the total area of the functional patterns 302. In another embodiment, the total area of the non-functional patterns 310 may be designed to be substantially less than about 80% of the total area of the functional device 300. The total area of the functional device 300 includes functional patterns 302 as well as non-functional patterns 310. Furthermore, the total area of the functional device 300 may also include any and all remaining active or passive elements within the functional device 300. In still another embodiment, a pattern density of about 10% to 60% is preferred when adding functional patterns 302 and/or non-functional patterns 310 to the functional device 300. The pattern density is defined as the total area of the layers (including functional patterns 302 and non-functional patterns 310) divided by the total area of the functional device 300.

As illustrated, the non-functional patterns 310 have a certain minimum width 312 similar to that of the minimum width 308 of the functional pattern 302. In one embodiment, the spacing 314 between the functional pattern 302 and the non-functional pattern 310 may be designed to be substantially at least half of the minimum width 308 of the functional pattern 302. In another embodiment, the spacing 314 between the functional pattern 302 and the non-functional pattern 310 may be designed to be substantially no greater than one and one-half times or 150% of the minimum geometric dimension 316 of the functional device 300. More specifically, the spacing 314 may be designed to be substantially no greater than 85% of the minimum geometric dimension 316.

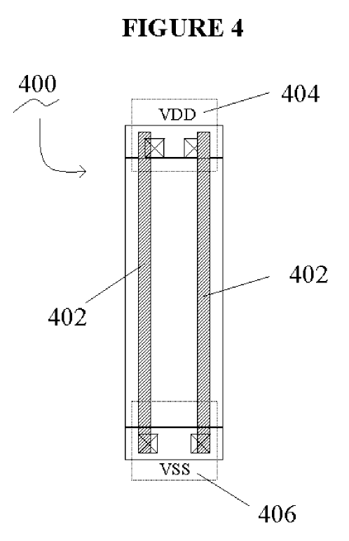

In another embodiment, at least a layer of filler cells 400 containing one or more non-functional patterns 402 may be used within an IC layout design. FIG. 4 illustrates a filler cell 400 that includes no functional patterns or functional devices. The layer of filler cells 400 may have one or more non-functional patterns 402 along with a VDD 404 and a VSS region 406. As illustrated in the figure, the non-functional patterns 402 can, but need not, contact the VDD region 404 and the VSS region 406.

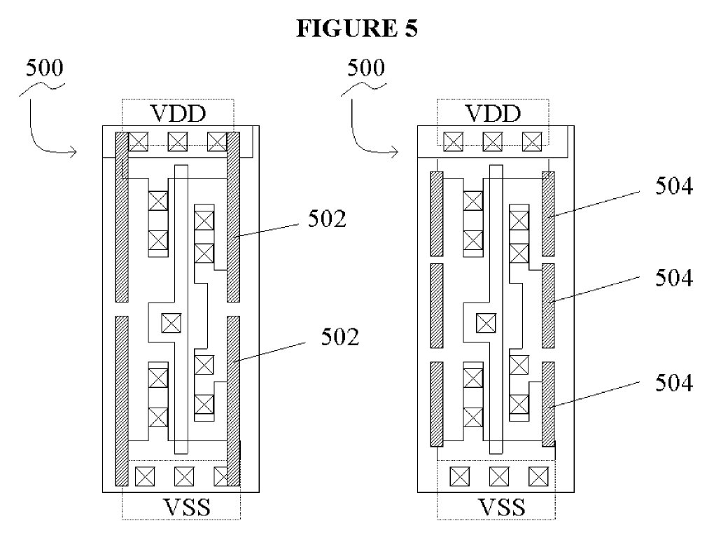

FIG. 5 illustrates how non-functional patterns 502, 504 may take on a variety of shapes and sizes. As illustrated by the two functional devices 500, instead of having a single rectangular non-functional pattern as illustrated in previous figures, the presently disclosed embodiment of non-functional patterns 502 may be broken up into two different sections 502. Alternatively, they may be separated into three different sections 504. These non-functional patterns 502, 504 may take on a variety of shapes and sizes and that the optimum design may require additional design of experiments (DOE). Furthermore, the non-functional patterns 502, 504 also may or may not contact the VDD or VSS region.

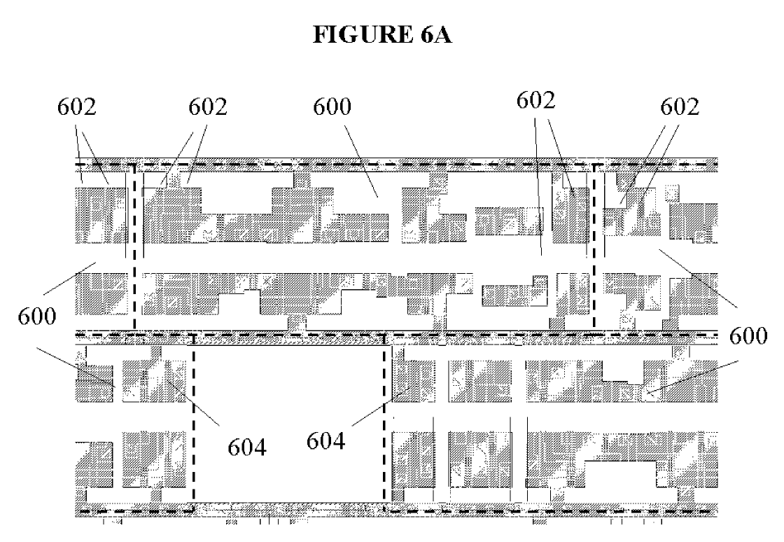

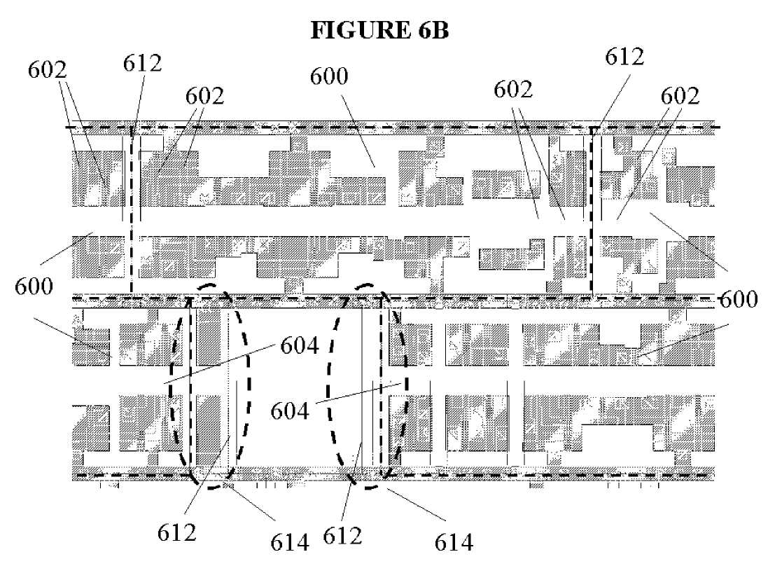

FIGS. 6A-6B compares a conventional IC layout design without the presently disclosed embodiments (FIG. 6A) versus an IC layout design using the presently disclosed embodiments (FIG. 6B). A series of functional devices 600 (dashed rectangular outlines) are illustrated in FIG. 6A. These functional devices 600 may include the likes of logic cells such as INV, NAND, NOR, AND, XOR, or F/F circuits. The functional devices 600 may also include multiplexers. As illustrated, the functional devices 600 may contain both densely-packed functional patterns 602 and isolated functional patterns 604. The functional patterns 602, 604 may or may not be formed on the same layer. The functional patterns 602 are densely-packed because they have neighboring functional patterns 602, while functional patterns 604 are isolated 604 because they have no neighboring functional patterns in close proximity. These functional patterns, whether densely packed 602 or isolated 604, may be a layer of polysilicon material, a metallic layer, a layer of semiconductor gates, or a layer of active transistors or conductive patterns and circuits. As discussed earlier, without using the presently disclosed embodiments, a conventional array of densely-packed functional patterns 602 and a conventionally isolated functional pattern 604 within a common IC layout design will print with different critical dimensions on an underlying wafer due to the iso-dense bias effect.

Taking the layout in FIG. 6A, a layer of non-functional patterns 612 and a layer of filler cells 614 (dashed oval outlines) may be added to improve feature fidelity and uniformity as illustrated in FIG. 6B. The layer of non-functional patterns 612 may or may not be formed on the same layer as that of the layer of filler cells 614. As shown in the top row of FIG. 6B, a layer of non-functional patterns 612 may be formed near the perimeters of functional devices 600. Although the densely-packed functional patterns 602 will have areas of maximum and minimum intensity, adding the layer of non-functional patterns 612 transforms the row of densely-packed functional patterns 602 into one large densely-packed array. In other words, instead of a row of functional devices 600 with individual pockets of densely-packed functional patterns 602, the non-functional patterns 612 balance the functional devices 600 to provide a relatively consistent component pattern for the device layers. This approach improves feature fidelity for the functional patterns 602 and improves the uniformity of features across a wafer.

Looking now at the bottom row of FIG. 6B, at least a layer of filler cells 614 may be formed substantially adjacent to isolated functional patterns 604. Inside the filler cells 614 may be one or more non-functional patterns 612. The non-functional patterns 612 balance the functional devices 600 to provide a relatively consistent component pattern for the device layer. Although not illustrated, additional filler cells 614 or non-functional patterns 612 may be formed between the filler cells 614 in the bottom row for further improvements in feature size fidelity. Furthermore, etching bias will be reduced because of the feature fidelity and uniformity. Etching bias occurs after photolithography where feature sizes with different critical dimensions will be transferred into the underlying layer resulting in non-uniform lines and contact holes. By making functional patterns across a wafer uniformly dense, etching bias is minimized and the overall device yield will thereby improve.

The benefits of the presently disclosed embodiments not only minimize the iso-dense bias effect, they also improve feature size fidelity and uniformity across a wafer. Although there are certain design requirements to follow for utilizing the presently disclosed embodiments, the basic design rules still have to be followed. In other words, an IC layout designer should not break the fundamental design rules simply because of his or her desire to use the presently disclosed embodiments. Furthermore, the presently disclosed embodiments may also save layout space because isolated devices may now be placed closer to each other without any layout rule constraints or photolithographic iso-dense bias concerns.

It will be appreciated by those of ordinary skill in the art that the invention can be embodied in other specific forms without departing from the spirit or essential character thereof. The presently disclosed embodiments are therefore considered in all respects to be illustrative and not restrictive. The scope of the invention is indicated by the appended claims rather than the foregoing description, and all changes that come within the meaning and ranges of equivalents thereof are intended to be embraced therein.

Additionally, the section headings herein are provided for consistency with the suggestions under 37 C.F.R. §1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Neither is the “Summary” to be considered as a characterization of the invention(s) set forth in the claims found herein. Furthermore, any reference in this disclosure to “invention” in the singular should not be used to argue that there is only a single point of novelty claimed in this disclosure. Multiple inventions may be set forth according to the limitations of the multiple claims associated with this disclosure, and the claims accordingly define the invention(s), and their equivalents, that are protected thereby. In all instances, the scope of the claims shall be considered on their own merits in light of the specification, but should not be constrained by the headings set forth herein.

What is claimed is:

1. A semiconductor device, comprising:
a plurality of layers patterned into functional patterns, the semiconductor device at least partially formed from the functional patterns; and
at least one of the plurality of layers further comprising non-functional patterns, the non-functional patterns being formed adjacent to the at least one layer's functional patterns to make a composite pattern of the at least one layer, whereby the feature density of the composite pattern is substantially more balanced.

2. The device according to claim 1, wherein the substantially more balanced feature density is operable to control image intensity profiles on a localized level.

3. The device according to claim 1, wherein the substantially more balanced feature density is operable to optimize the loading effects on a global wafer level.

4. The device according to claim 1, wherein a spacing between the functional patterns and the non-functional patterns is at least half of a minimum geometric dimension of the functional patterns.

5. The device according to claim 1, wherein a spacing between the functional patterns and the non-functional patterns is no greater than 85% of a minimum geometric dimension of the device.

6. The device according to claim 1, wherein a total area of the non-functional patterns is substantially the same as a total area of the device.

7. The device according to claim 1, wherein a total area of the non-functional patterns is substantially less than 80% of a total area of the device.

8. The device according to claim 1, wherein the non-functional pattern comprises a semiconductor material.

9. The device according to claim 1, wherein the non-functional pattern comprises a polygon.

10. A semiconductor device structure comprising a plurality of functional devices, the functional devices comprising:
a plurality of layers patterned into functional patterns; and
a plurality of non-functional patterns, the non-functional patterns being formed adjacent to the at least one layer's functional patterns to make a composite pattern of the at least one layer, whereby the feature density of the composite pattern is substantially more balanced.

11. The structure according to claim 10, wherein the substantially more balanced feature density is operable to control image intensity profiles on a localized level.

12. The structure according to claim 10, wherein the substantially more balanced feature density is operable to optimize the loading effects on a global wafer level.

13. The structure according to claim 10, wherein a spacing between the functional structures and the non-functional structures is no greater than 85% of a minimum geometric dimension of the structure.

14. The structure according to claim 10, wherein a total area of the non-functional structures is substantially less than 80% of a total area of the structure.

15. The structure according to claim 10, wherein the non-functional structures comprise polygons.

16. A method of producing a semiconductor device, the method comprising:
patterning a plurality of layers into functional patterns, the semiconductor device at least partially formed from the functional patterns; and
forming at least one or more plurality of layers further comprising non-functional patterns, the non-functional patterns being formed adjacent to the at least one layer's functional patterns to make a composite pattern of the at least one layer, whereby the feature density of the composite pattern is substantially more balanced.

17. The method according to claim 16, wherein the photomask comprises the functional patterns adjacent to the non-functional patterns having a spacing between the functional patterns and the non-functional patterns of at least half of a minimum geometric dimension of the functional patterns.

18. The method according to claim 16, wherein the photomask comprises the functional patterns adjacent to the non-functional patterns having a spacing between the functional patterns and the non-functional patterns of no greater than 85% of a minimum geometric dimension of the semiconductor device.

19. The method according to claim 16, wherein the photomask comprises the functional patterns adjacent to the non-functional patterns having a total area of the non-functional patterns being substantially the same as a total area of the functional patterns.

20. The method according to claim 16, wherein the photomask comprises the functional patterns adjacent to the non-functional patterns having a total area of the non-functional patterns being substantially less than 80% of a total area of the semiconductor device.
